(19) United States
(12) Patent Application Publication
(10) Pub. No.: US 2026/0338891 A1
(43) Pub. Date: Oct. 29, 2026

(54) Three-Dimensional Echo-Planar Imaging Including Random Sampling

(71) Applicant: Siemens Healthineers AG, Forchheim (DE)

(72) Inventors: Jin Jin, Chapel Hill (AU); Marcel Dominik Nickel, Herzogenaurach (DE); Kieran O'Brien, West End (AU)

(73) Assignee: Siemens Healthineers AG, Forchheim (DE)

(21) Appl. No.: 19/656,022

(22) Filed: Apr. 23, 2026

Related U.S. Application Data
(60) Provisional application No. 63/793,752, filed on Apr. 24, 2025.

(51) Int. Cl. G01R 33/48; G01R 33/56

(52) U.S. Cl. CPC G01R 33/482; G01R 33/5608

(57) ABSTRACT

A method is provided for acquiring magnetic resonance (MR) image data of an object by performing a three-dimensional echo-planar imaging sequence. The imaging sequence samples a three-dimensional k-space via at least one shot, each shot comprising applying a radio-frequency excitation to the object to generate an MR signal, spatially encoding the MR signal along two phase-encoding directions ky and kz, which together span a phase-encode plane, via gradients in the phase-encoding directions, and acquiring k-space lines at different positions in the phase-encode plane while applying read-out gradients along a frequency encoding direction kx. The k-space is sampled in a pattern that undersamples the k-space in the phase-encode plane. The sampling pattern is generated by receiving a parallel imaging sampling pattern and introducing random or pseudo-random jitter, such that one or more k-space lines are shifted with respect to the parallel imaging sampling pattern in the ky and/or the kz direction.

### CROSS-REFERENCE TO RELATED APPLICATIONS

This application claims priority to U.S. provisional application No. 63/793,752, filed on Apr. 24, 2025, the contents of each of which are incorporated herein by reference in their entirety.

### TECHNICAL FIELD

The disclosure is directed to techniques for implementing three-dimensional echo-planar imaging (3D-EPI) as part of a magnetic resonance imaging (MRI) examination and, more particularly, to the use of random sampling in combination with deep-learning based iterative reconstruction to achieve higher acceleration without introducing under-sampling artifacts.

### BACKGROUND

MRI is a slow medical imaging modality relative to others, such as X-ray and CT. The long scan time stems from the repeated acquisitions with varied phase encoding, which are necessary to localize the signal source of individual voxels to form an image. Three-dimensional (3D) echo-planar imaging (EPI) is one of the “fast” acquisition sequences, in which multiple lines of the 3D k-space are acquired with every excitation.

To provide further acceleration, 3D-EPI has also been combined with parallel imaging approaches, such as SENSE, GRAPPA, CAIPIRINHA and Skipped-CAIPI. In parallel imaging, the fact that the magnetic resonance (MR) signal is acquired with multiple receiver coils, which are placed at different positions around the body part, is exploited. In particular, if the spatially varying sensitivity profiles of the individual receiver coils is known, this information can be used to assist in the spatial localization of the MR signal. Having this additional information about the coil sensitivity profiles allows a reduction in the number of phase-encoding steps during image acquisition, i.e. the k-space is undersampled by an acceleration factor which is called “acceleration” or “parallel imaging acceleration.” This, in turn, allows for a reduction in acquisition time. However, such approaches to date have various drawbacks and are thus inadequate.

### SUMMARY

When combining 3D-EPI with parallel imaging approaches, the acceleration limit is eventually reached as the acceleration factor increases, i.e. when the image quality starts to degrade, as manifested as image artifacts and/or low image SNR. It has been previously demonstrated that random sampling, when combined with a suitable reconstruction strategy, is an effective means of achieving higher acceleration while avoiding image artifacts and/or preserving SNR. The reason is that random sampling spreads the “missing” information across k-space in a way which is favorable for Compressed Sensing (CS) reconstructions algorithms. Compressed Sensing works well when the image is sparse in some domain, e.g. the wavelet domain, and when the sampling is incoherent. The principles of Compressed Sensing are explained for example in references [1] and [2].

Traditionally, one of the bottlenecks of such methods is to implement random sampling in the acquisition. To this end, random sampling has been implemented in a retrospective fashion in early studies [1], and prospectively for various sequences, such as spin echo [1], gradient echo [2],[3], and for more advanced trajectories, such as radial [4],[5]. Recently, random sampling has also been combined with 3D-EPI in two different publications by Liebig et al. [6],[7].

The key idea of the first approach [6] is to generate sampling patterns with random step sizes in one or both phase-encoding directions (ky and kz). Thereby, the degree of undersampling is varied across the k-space, using a higher degree of undersampling in the outer k-space regions, and a lower degree of undersampling in the central region of the k-space. The largest challenge with this approach is in the implementation. In the approach tested by Liebig et al. in [6], the imaging sequence was not actually implemented. Rather, MR raw data was synthesized from a fully sampled 3D multi-contrast, gradient echo image. Thereby, the efficacy of the sampling scheme in achieving good image quality could be tested, but not whether such an approach can actually be implemented on a scanner.

The difficulty with such an implementation is twofold. Firstly, a k-space ordering scheme needs to be devised to sample all the desired read-out lines in an efficient fashion. Secondly, such an ordering scheme should resemble an EPI readout. However, randomly-generated step sizes in the phase-encode plane in an EPI scheme either requires a variable echo spacing, or having a fixed echo spacing that can accommodate the largest of all the random steps. The former approach is typically associated with variable distortion due to variation in echo-spacing at different parts of k-space, resulting in blurring in the image, whereas the latter approach is inefficient for an EPI read-out. In the sampling scheme proposed by Liebig et al. in [6], large step sizes were used at the expense of having only 5 echoes per shot. Thus, this approach seems be rather inefficient.

The second approach [7] of the two randomly sampled 3D-EPI approaches is based on read-out segmented EPI. Therein, the segmentation is performed in the kx-ky plane and specifically in the kx (i.e., the read-out) direction. This means that each echo does not read out a full k-space line, but only part of it. The conventional read-out segmented EPI aims to shorten TEs compared to a conventional single-shot EPI by segmenting the k-space in read-out (kx) direction, hence reducing the analog-to-digital converter (ADC) open times. To implement variable sampling density while maintaining the same echo spacing between different segments, the segments were made to have different sizes (i.e., width in kx direction). For example, the segments at outer k-space are wider with fewer readout lines along ky, resulting in the same effective echo spacing compared to the segments in the middle of k-space, which aims to avoid image blurring due to variable echo spacing. However, there are drawbacks of such an approach, which are similar to those of the conventional read-out segmented EPI. In particular, this approach is still associated with relatively long TE times due to the time required to play out gradient blips in each segment to traverse k-space in the ky direction. As the segments become narrower for shorter ADC open times and shorter TE, ky gradient blips start to account for more of the total acquisition time. Furthermore, narrower segments require additional segments in the long kx direction, exacerbating the inefficiency. Further, no randomness is present in the sampling.

According to embodiments of the present disclosure, a method for acquiring magnetic resonance (MR) image data of an object by performing a three-dimensional echo-planar imaging sequence is provided. The imaging sequence comprises:
sampling a three-dimensional k-space via at least one shot comprising:
applying a radio-frequency (RF) excitation to the object to generate an MR signal;
spatially encoding, via gradients in the phase-encoding directions, the MR signal along two phase-encoding directions k_{y} and k_{z} that together span a phase-encode plane; and acquiring, while applying read-out gradients along a frequency encoding direction kₓ, a number of k-space lines at different positions in the phase-encode plane,
wherein the k-space is sampled in a sampling pattern that undersamples the k-space in the phase-encode plane, and
wherein the sampling pattern includes a random or pseudo-random jitter such that one or more k-space lines are randomly or pseudo-randomly shifted in the k_{y} and/or the k_{z} direction.

In useful embodiments, the sampling pattern is essentially a regular sampling pattern, such as a parallel imaging sampling pattern, to which relatively small jitter is introduced or added. Thus, some or all of the k-space lines are shifted with respect to the underlying regular sampling pattern by a small, random shift (jitter). If a random shift is added to all k-space lines, the shift can also be zero, for example according to a random distribution.

This acquisition method has the following advantages: Firstly, the proposed approach provides a random sampling pattern that largely follows the parallel imaging approach, hence inheriting its benefits, including complete flexibility in configuring the overall acceleration factor, sampling pattern and EPI train length. Specifically, in embodiments where a segmented acquisition is used, the EPI echo train length can be adjusted by adjusting the number of segments. This is not feasible with the conventional method [7] in which the EPI echo train length is determined by the image matrix size in the ky direction.

Secondly, the randomness in sampling of the proposed approach is achieved by jitters in the phase-encoding directions, i.e. additional gradients in kz or ky are being superimposed on top of the parallel imaging gradients, such as gradient pulses or gradient blips. As a result, the actual gradient pulse blip sizes when using random sampling is similar to and sometimes no larger than those which would be used for the underlying regular sampling pattern, in particular if this is a skipped-CAIPI sampling pattern. This results in similar echo spacing and overall sequence timing with and without random sampling. This is highly advantageous, since variable echo spacing would induce B0-related artifacts, for example due to eddy currents. Therefore, it is important that each phase encode gradient can be fitted into the time gap allowed in the sequence timing of the underlying (parallel imaging) sequence. Due to the fact that randomness is introduced into the sequence in the form of small jitter, this is the case in most embodiments of the present disclosure.

According to embodiments of the present disclosure, the MR image data is acquired in k-space, as is usual for echo-planer imaging (EPI). As is generally known, the k-space is sampled by means of at least one shot, wherein several k-space lines are acquired in each shot, and a 3D k-space is typically sampled by means of multiple shots. However, it is possible to acquire a complete k-space in one shot if k-space is small, i.e. having low resolution, and one can tolerate poorer image quality. The radio-frequency (RF) excitation, also referred to as RF pulse, may be selective or non-selective. A selective RF pulse may be played out in the presence of a gradient field in the slice-selection direction. This direction is herein referred to as kz. Thereby, a slab of tissue within the object may be excited. However, the RF pulse may also be non-selective, especially if the RF pulse is applied using an RF coil which limits the field of view.

According to embodiments of the present disclosure, the MR signal is spatially encoded along two phase-encoding directions, ky and kz, which together span a phase-encode plane, by means of gradients in the phase-encoding directions. The gradients may be applied as gradient pulses or “gradient blips.” Thereby, the signal is shifted in the phase-encode plane, between the readouts, i.e. when k-space lines are acquired while applying read-out gradients along a frequency encoding direction kx.

The object may be any suitable one, e.g. an animal or human, such as a patient or subject. The object may also be any suitable part of a subject or patient, such as the head, a limb, the chest, the abdomen or the hip, or a particular organ in the body, or parts of the aforementioned.

According to embodiments of the present disclosure, the sampling pattern may comprise a parallel imaging sampling pattern before the random or pseudo-random jitter is introduced, as for example explained in [9] and [11]. In parallel imaging, the undersampling is compensated by also considering spatial information from the RF receive coil, e.g. if the RF receive coil comprises several small individual coils arranged at different positions around the object, such as for example a phase-array coil. Thus, while the k-space is in principle sampled on a Cartesian grid, not all k-space lines on the grid are acquired. For example, only every Rth line may be acquired, resulting in an acceleration of R. The sampling pattern is generally regular, i.e. repetitive.

According to embodiments of the present disclosure, the sampling pattern is generated by receiving a parallel imaging sampling pattern; and a random or pseudo-random jitter is introduced such that one or more k-space lines are randomly or pseudo-randomly shifted with respect to the parallel imaging sampling pattern in the ky and/or the kz direction.

In accordance with embodiments of the disclosure, the sampling pattern, e.g. the sampling pattern in the phase-encode plane, includes a random or pseudo-random jitter such that one or more k-space lines are randomly or pseudo-randomly shifted with respect to the parallel imaging sampling pattern in the ky and/or the kz direction. The ky and the kz direction are the phase-encoding directions, and together span the phase-encode plane. The term “pseudo-randomly” as used herein may mean that the randomness is generated by a computer algorithm. Therefore, it may not be “purely” random, but may be generated in a pre-determined manner or in any suitable manner that is accepted as being sufficient randomized as part of an applicable process. That is, for the present purposes, the jitter is sufficiently random to achieve beneficial effects on the MR image quality caused by incoherent sampling. Therefore, throughout the disclose the terms “random” and “pseudo-random” are used interchangeably.

The “jitter” may mean a certain random shift in the phase-encoding directions. Such jitter may be small in comparison to the size of the k-space. For instance, the jitter may be of the same order of magnitude as the steps in the phase-encode plane between the different k-space lines according to the underlying regular sampling pattern, e.g. the parallel imaging sampling pattern. As an illustrative example, the mean magnitude of the jitter in the positive or negative directions (i.e. the mean absolute jitter) may be between any suitable range, such as for instance between 0.1R and 2R, between 0.5R and R, etc., with R representing the acceleration in the specific k-space direction. In this way, the readout pattern is made irregular and random, but its basic structure is preserved, preserving its advantages. The jitter size may be represented as an integer number without units as it refers to the k-space positions on the grid on which the k-space lines are acquired in the phase-encode plane. Embodiments described herein are directed to the sampling pattern, i.e. the pattern of acquired k-space lines. The order in which the k-space lines are acquired, also referred to as sampling order or reordering, may remain the same as used in the underlying parallel imaging sequence. The sampling order, as well as the acceleration and the number of segments, may be varied according to the needs of the specific application.

In accordance with embodiments of the disclosure, the parallel imaging sampling pattern is a SENSE/GRAPPA sampling pattern before the random or pseudo-random jitter is introduced. GRAPPA (Generalized Autocalibrating Partially Parallel Acquisitions) and SENSE (Sensitivity Encoding) are two known methods in parallel MRI used to accelerate image acquisition by reducing the number of phase-encoding steps. They both utilize multi-channel coil data but differ in their approach to reconstructing the missing k-space data. GRAPPA reconstructs missing k-space data through linear combinations of acquired data, while SENSE reconstructs the image directly using coil sensitivity map.

The SENSE/GRAPPA sampling pattern is exemplified in FIG. 2C and explained in further detail in [13]. As is generally known, SENSE and GRAPPA use a simple undersampling pattern in which only every Rth k-space line is acquired in one or both phase-encoding directions, resulting in an acceleration R. Thus, a jitter may be introduced into a phase-encoding direction having an acceleration R>1, preferably the phase encode-encoding direction having the highest acceleration.

In accordance with embodiments of the disclosure, the parallel imaging sampling pattern is a Controlled Aliasing in Parallel Imaging Results in Higher Acceleration (CAIPIRINHA) sampling pattern before the random or pseudo-random jitter is introduced. CAIPIRINHA uses a sampling pattern wherein the k-space lines are shifted from one another by applying additional offsets to the phase-encoding gradients, as shown in FIG. 2D. This may reduce pixel aliasing and overlap on reconstructed images. This sampling pattern also lends itself to introducing random jitter.

In accordance with embodiments of the disclosure, the parallel imaging sampling pattern is a skipped Controlled Aliasing in Parallel Imaging (skipped-CAIPI) sampling pattern before the random or pseudo-random jitter is introduced.

The skipped-CAIPI has the advantage that the sampling order, also referred to as reordering, may comprise jumps between partitions. Partition direction is synonymous with kz direction in the current context. By “jumping” between partitions, the phase-encode gradient blips include components in both the ky and the kz direction. However, the overall step sizes may be made smaller, thereby allowing for faster acquisition. This sampling pattern lends itself particularly well for introducing the random jitter described herein. According to embodiments of the present disclosure, the MR data is acquired largely following the skipped-CAIPI pattern, while allowing small jitters in the phase-encoding directions, e.g. in the kz direction.

CAIPIRINHA may be considered a “special case” of skipped-CAIPI, with the condition that kz gradient blip is zero within the same shot/segment, and GRAPPA/SENSE may be considered a “special case” of CAIPIRINHA, with the condition that the CAIPIRINHA shift Δy or Δz is zero.

In accordance with embodiments of the present disclosure, the k-space is not segmented in the readout direction (kx). In other words, each readout line covers the full k-space in readout direction. Thereby, the disadvantages of a readout-segmented EPI protocol may be avoided, for example that the readout gradient needs to switch even more quickly, and more frequently. This leads to more time spent on readout gradient switching and overall lower sampling efficiency with the readout-segmented EPI.

In accordance with embodiments of the present disclosure, the k-space is divided in the second phase-encoding direction kz into a series of blocks, with each block being acquired in one or a plurality of shots or segments. A block may comprise any suitable number of partitions, e.g. one or several partitions. In accordance with the present embodiment, a shot does not sample data from more than one block, thereby making the sequence timing more regular. The second phase-encoding direction kz may correspond for instance to the slice selection direction.

In accordance with embodiments of the present disclosure, each block is acquired in a segmented fashion using multiple shots or segments. Thereby, the echo train length (ETL) can be reduced, which is advantageous to improve image quality. According to such embodiments, the number of segments may be individually adjusted to the specific application and according to the user requirements. In some embodiments, the EPI readout line positions in kz direction of a particular shot are restricted to a block of a predetermined size. If this is the case, the jitter is adjusted accordingly, so as not to shift a k-space line into the adjacent block.

The embodiments discussed herein demonstrate that random sampling can be implemented with segmented 3D-EPI in a straightforward manner. This new acquisition is able to achieve higher acceleration without under-sampling artifacts, especially when combined with a deep-learning based iterative reconstruction.

In accordance with embodiments of the present disclosure, the k-space is divided in the second phase-encoding direction kz into a series of partitions, and the k-space direction in which the one or more k-space lines are shifted to include the random or pseudo-random jitter comprises the kz direction. In some embodiments, the jitter is introduced in both phase-encoding directions. In other embodiments, the jitter is introduced in one phase-encoding direction only, for example the kz direction. Thereby, a regular step size in ky direction can be maintained, resulting in an advantageous sequence timing. In some embodiments, the EPI readout line positions in the kz direction, Kz, of a particular shot are restricted to a particular block of size Rz, namely Kz∈[(q−1)Rz+1,qRz] for the q-th block.

In accordance with embodiments of the present disclosure, the k-space lines are shifted in one single phase-encoding direction to include the random or pseudo-random jitter. This may be the kz direction or, alternatively, the ky direction.

In accordance with embodiments of the present disclosure, the random or pseudo-random jitter is generated during preparation of the imaging sequence. Thereby, the randomness may be integrated into currently used sequences, e.g. parallel imaging sequences. The overall sequence programming may remain the same, with merely an additional step of slightly shifting the k-space positions, by means of small random changes in the gradient blip sizes in one or both phase-encoding directions.

In accordance with embodiments of the present disclosure, the random or pseudo-random jitter is generated according to a probability density function (PDF). A PDF describes the likelihood of a continuous random variable falling within a particular range of values. Examples include a normal distribution or a Gaussian distribution. A PDF may be defined by a mean or expectation value, and by a variance. The random jitter may be generated by using a random number generator, which can be implemented in software (a pseudorandom number generator or PRNG) or hardware (a true random number generator or TRNG). PRNGs use algorithms to produce sequences of numbers that appear random, even though they are in fact predetermined by the algorithm.

In accordance with embodiments of the present disclosure, the sampling pattern is arranged on a Cartesian grid in the phase-encode plane, and the random or pseudo-random jitter has an absolute value between any suitable range of grid points, e.g. between 0 and 5 grid points. This may also be varied according to the acceleration.

In accordance with embodiments of the present disclosure, the parallel imaging sampling pattern has an acceleration factor in at least one phase-encoding direction, and the random or pseudo-random jitter introduced in that direction has an absolute value between 0 and the acceleration factor, or between 0 and any suitable proportion of the acceleration factor, e.g. half the acceleration factor. Thereby, a small jitter can be introduced.

In some embodiments, the random or pseudo-random jitter may be generated by a PDF having a mean absolute value between any suitable values, such as for instance between 0.5 and 8, between 1 and 5, etc. The random or pseudo-random jitter may also be generated by a PDF having a mean absolute value between any suitable values, for instance between 0.1 and 2, between 0.5 and 1, etc., of the acceleration R in the respective phase-encoding direction. The variance of the PDF may also be any suitable value, for instance a value between 0.02 and 0.5, for example about 0.1.

In accordance with embodiments of the present disclosure, the k-space is divided in the second phase-encoding direction kz into a series of partitions, and the random or pseudo-random jitter has a negative or non-negative value based upon a sequential number of the one or more of the series of partitions to which the jitter is introduced. Thereby, it can be assured that the k-space lines of each shot remain in one block, irrespective of the jitter.

In accordance with embodiments of the present disclosure, a method for generating an imaging sequence for acquiring magnetic resonance (MR) image data of an object based on three-dimensional echo-planar imaging is provided, the method comprising:
using a sampling scheme in which a three-dimensional k-space is sampled via at least one shot comprising:
applying a radio-frequency (RF) excitation to the object to generate an MR signal;
spatially encoding, via gradients in the phase-encoding directions, the MR signal along two phase-encoding directions k_{y} and k_{z} that together span a phase-encode plane;
acquiring, while applying read-out gradients along a frequency encoding direction kₓ, a number of k-space lines at different positions in the phase-encode plane,
wherein the k-space is sampled in a sampling pattern that undersamples the k-space in the phase-encode plane; and
generating the sampling pattern by:
receiving a parallel imaging sampling pattern; and
introducing a random or pseudo-random jitter such that one or more k-space lines are randomly or pseudo-randomly shifted with respect to the parallel imaging sampling pattern in the k_{y} and/or the k_{z} direction.

Thereby, an MR imaging sequence may be generated, which can be used to acquire the MR image data in an acquisition method as described herein. All features and advantages disclosed with respect to the acquisition method also apply to the generation method, and vice versa. As noted above, the jitter may be advantageously introduced when the sequence is generated. The methods may be performed by an MR scanner as disclosed herein.

In accordance with embodiments of the present disclosure, a method for reconstructing a magnetic resonance (MR) image from MR data acquired of an object is provided, the method comprising:
receiving magnetic resonance (MR) image data of an object in k-space, the data acquired by a method for performing three-dimensional echo-planar imaging, as disclosed herein; and
applying a deep-learning based reconstruction algorithm to the k-space data to thereby generate a reconstructed image.

Thereby, the advantages of the random acquisition sampling pattern are best exploited. Advantageously, the image reconstruction may be adapted to the acquisition method, e.g. to the sampling pattern.

In accordance with embodiments of the present disclosure, the method comprises a further step of applying a deep learning based super-resolution algorithm to the reconstructed image, to thereby generate an image having improved resolution. Thereby, the image quality may be further improved. In this embodiment, the deep learning reconstruction comprises two independent, sequential processing steps. Firstly, images are generated on the acquired resolution, for example using a variational network architecture as explained below. Secondly, the obtained images may be interpolated using a deep learning based super-resolution algorithm, for example as disclosed in [17], for example with a factor-of-two interpolation in all spatial dimensions.

In accordance with embodiments of the present disclosure, the deep-learning based reconstruction algorithm comprises a variational network architecture comprising a plurality of iterations of a parallel-imaging type reconstruction step, an image regularization step, and a data consistency step. Thereby, a reconstruction similar to Compressed Sensing may be implemented. The parallel-imaging type reconstruction step may use a calibration step during the MR examination to estimate coil sensitivities or interpolation kernels. In the parallel-imaging type reconstruction step, the acquired MR data is used to reconstruct a full image, wherein the missing k-space data is estimated using the calibration data, if applicable. This may be done using image-domain methods (e.g., SENSE), and/or using coil sensitivity information to “unfold” the aliased images. Alternatively, the reconstruction may be performed in the k-space domain (e.g., GRAPPA). These methods function to estimate the missing k-space data points using an interpolation kernel based on the acquired calibration data, and then reconstruct the image using the full k-space data. Individual coil images are reconstructed from the undersampled data and then combined. Thus, an estimate of the 3D image is reconstructed. A regularization is then applied to this image, for example using U-nets, a particular type of artificial neural network (NN). Typically, a data consistency step is then performed. Therein, the regularized image is transferred back into k-space and brought into consistency with the data that was acquired. In embodiments, these steps are iterated any suitable number of times, e.g. 2 to 10 of times, 3 to 8 times, etc. In the example explained below, six iterations alternated between parallel imaging reconstruction and 3D image regularizations using U-nets [10] were performed. The network parameters were then determined through supervised training based on about 500 fully sampled 3D datasets of head, abdomen, and pelvis from healthy volunteers (no 3D-EPI data included). Thereby, superior image quality could be realized in the reconstructed image.

In accordance with embodiments of the present disclosure, a non-transitory storage medium comprising program code is provided, wherein the program code is configured to, when executed by suitable components such as processing circuitry, cause a computer or other suitable computing component to perform the generation method, the reconstruction method, and/or the acquisition method, execute the program code. The storage medium may be any suitable non-transitory computer-readable medium. The computer-readable medium may be any digital storage medium, such as a hard disc, a cloud, an optical medium such as a CD or DVD, a memory card such as a compact flash, memory stick, a USB-stick, multimedia stick, secure digital memory card (SD), etc.

In accordance with embodiments of the present disclosure, a magnetic resonance imaging device for performing three-dimensional echo-planar imaging (3D-EPI) of an object is provided. The device comprises:
a main magnet, and gradient coils; and
processing circuitry configured to:
acquire magnetic resonance (MR) image data of an object by performing a three-dimensional echo-planar imaging sequence, the imaging sequence comprising:
sampling a three-dimensional k-space by means of at least one shot, each shot comprising:
applying a radio-frequency (RF) excitation to the object to generate an MR signal
spatially encoding, via gradients in the phase-encoding directions, the MR signal along two phase-encoding directions k_{y} and k_{z} that together span a phase-encode plane; and
acquiring, while applying read-out gradients along a frequency encoding direction kₓ, a number of k-space lines at different positions in the phase-encode plane,
wherein the k-space is sampled in a sampling pattern that undersamples the k-space in the phase-encode plane, and
wherein the sampling pattern is generated by:
receiving a parallel imaging sampling pattern; and
introducing a random or pseudo-random jitter such that one or more k-space lines are randomly or pseudo-randomly shifted with respect to the parallel imaging sampling pattern in the ky and/or the kz direction.

In other words, the sampling pattern includes a random or pseudo-random jitter such that one or more k-space lines are randomly or pseudo-randomly shifted with respect to a parallel imaging sampling pattern in the k_{y} and/or the k_{z} direction.

The MRI device may have features of any suitable MR scanner. In embodiments of the present disclosure, the MRI device is configured to execute any of the methods as disclosed herein. All features and advantages disclosed with respect to the method also apply to the MRI device, and vice versa.

### BRIEF DESCRIPTION OF THE DRAWINGS

In the Figures:

FIG. 1 illustrates an example 3D EPI volume separated into shots in the kx-ky plane and partitions in the kz direction, in accordance with embodiments of the present disclosure;

FIGS. 2A-2G illustrate example sets of k-space sampling patterns, in accordance with embodiments of the present disclosure;

FIGS. 3A-3H illustrate example acquisition patterns for 3D-EPI with and without random jitters, in accordance with embodiments of the present disclosure;

FIG. 4 is a flow diagram of a reconstruction method, in accordance with embodiments of the present disclosure; and

FIG. 5 illustrates a representation of an example magnetic resonance device, in accordance with one or more embodiments of the present disclosure.

### LIST OF REFERENCE SIGNS

O Object
M Measurement Volume
1 Main Field Magnet
2 Shim Coils
3 Gradient Coils
4 RF coil
5 Magnetic Resonance Imaging Device
6 diplexer
7 RF amplifier
8 RF receiver channel
9 transmitting channel
10 control device
11 outputs
12 inputs
13 terminal
14 display screen
15 keyboard
16 mouse
17 image computer
18 sequence controller
19 synthesizer
20 control computer
21 DVD
22 RF system
23 table
24 RF power amplifier
25 Shim coils supply
30 center of k-space
32 k-space line
34 gradient blip
33 k-space line
36, 42 phase-encode planes
38 k-space line of second shot
40 k-space lines of third shot
44 fully samples k-space
45, 50, 51, 52, 55 phase-encode planes showing sampling patterns
45 k-space line of first shot
47 k-space lines of second shot
53, 54 jump between partitions
56 jump between partitions
60 original position on the phase-encode plane
61 position on the phase-encode plane with random jitter
B1, B2 blocks
62 k-space data as acquired
70 deep-learning based reconstruction algorithm
64 parallel-imaging type reconstruction step
66 image regularization step
68 data consistency step
72 deep-learning based super-resolution algorithm
74 3D image

### DETAILED DESCRIPTION

### I. An Overview of Sampling Patterns with and without Acceleration for 3D-EPI

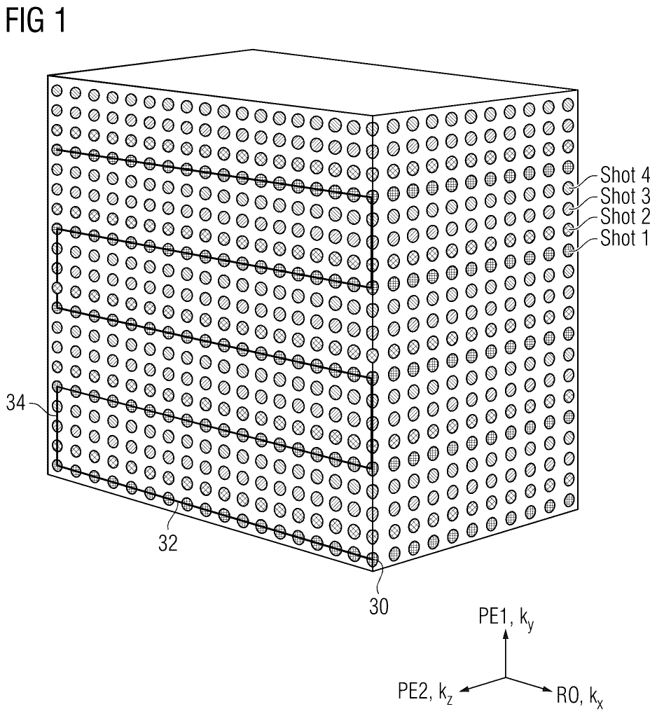

FIG. 1 illustrates an example 3D EPI volume separated into shots in the kx-ky plane and partitions in the kz direction, in accordance with embodiments of the present disclosure. The readout direction RO is the kx direction, and the phase-encoding directions (PE1 and PE2) are the ky and kz directions. The ky-kz plane is therefore also termed the phase-encode (or phase encoding) plane. The 3D k-space is sampled on a grid, which may be Cartesian, and each sample point on which data is acquired, as illustrated by a small circle in FIG. 1. The kz direction also corresponds to the slice-select direction in embodiments where slice/slab selective excitation pulses are used. The data points having the same kz belong to the same “partition.”

The origin of k-space is denoted at point 30. According to embodiments, the data sampling starts at this point in one particular shot. A readout gradient is then applied in some embodiments so that one line along the kx direction is sampled, as indicated by the straight line 32. When the end of the k-space in kx direction is reached, a phase encode gradient blip in ky direction is applied so that the k-space trajectory “jumps” several lines in the ky direction from 32 to 33. In line 33, the readout gradient is reversed, and another readout line is acquired along 33. Another gradient blip in the ky direction is then applied. This is repeated several times so that this shot acquires e.g. 5 readout lines, or a quarter of this partition. In other words, the 3D k-space is divided into 4 shots in the kx-ky plane (indicated with different patterns in the small circles) for each partition in the illustrated embodiment. Thus, and as illustrated in FIG. 1, with the segmented 3D-EPI approach the 3D k-space is acquired through a series of partitions (the number of kx-ky planes, or the number of kz samples), and each partition is acquired in a segmented fashion using multiple shots. In single-shot EPI, which may also be used in the context of the present disclosure, the partition is acquired in one-shot, which is essentially a special case of segmented EPI with no. of segments S=1.

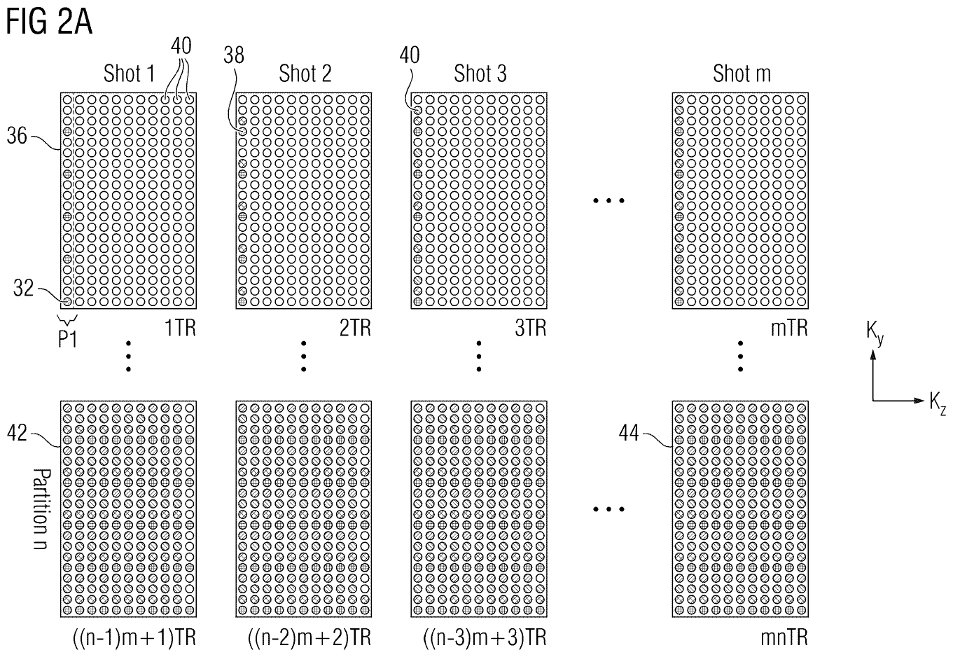

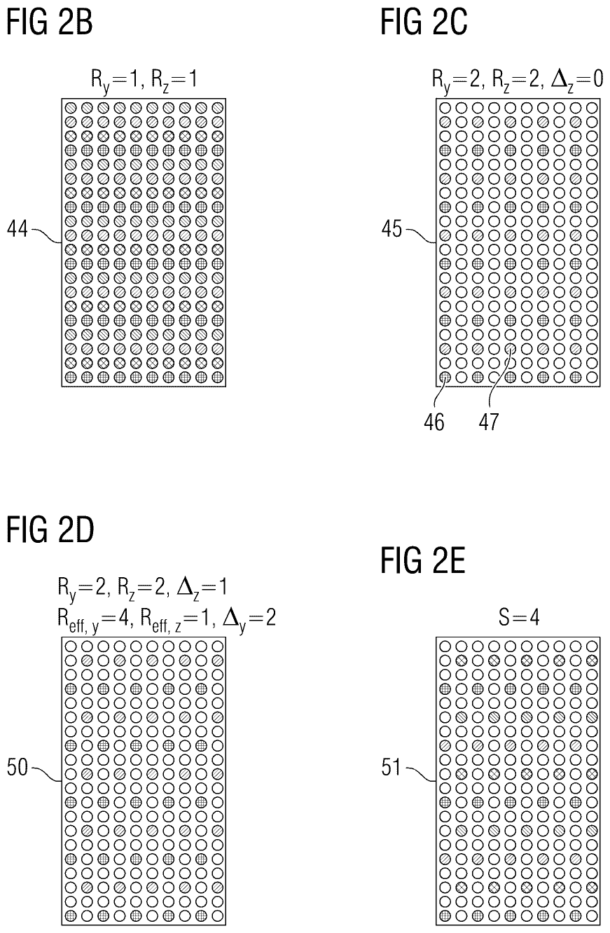

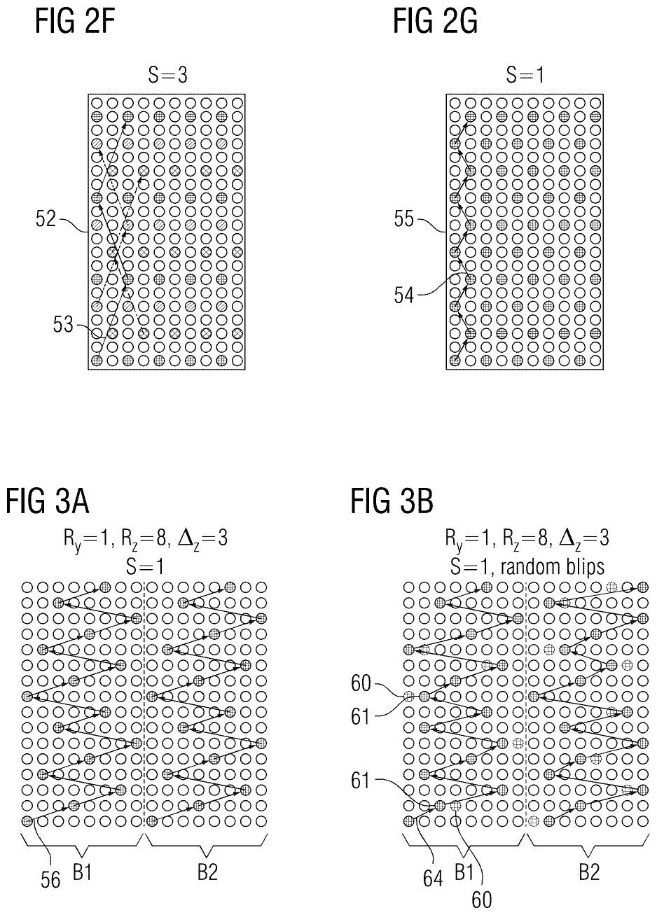

To simplify the illustration and discussion, the 3D plot of the k-space, as illustrated in FIG. 1, may be reduced to 2D plots showing only the phase-encode plane ky-kz, and this notation is used in the further figures. Therein, each readout line in kx-direction is indicated as one small circle 40 (see FIG. 2A).

FIG. 2A further illustrates the sampling scheme shown in FIG. 1, to show the order of 3D k-space acquisition. The first 4 rectangles show an example phase-encode plane 36, with the readout lines of one shot marked. In the first rectangle, after one repetition time (TR), 5 k-space lines 32 have been acquired in the first partition P1. The k-space lines 32 are distributed across the partition at regular intervals in ky-direction. In FIG. 2A, no parallel imaging is used. Thus, without acceleration, each partition P1, P2, P3, . . . can be readily divided into m segments (shot and segment are used synonymously), while n partitions are sampled in a repetitive fashion. The entire k-space thus requires mn TRs. The number of segments S for each shot is directly linked to the echo train length (ETL) and the matrix size in the phase-encoding direction N_{y}, S=N_{y}/ETL. In this (somewhat simplified) example, Ny=20, S=4, and ETL=5.

In the lower line of FIG. 2A, the sampling of the last partition n is illustrated. In 42, the first segment has been acquired, and in 44, the last segment. Thus, the total acquisition time for this 3D k-space is mn TR, where n is the no. of partitions and m is the number of segments per partition.

FIG. 2B to 2G illustrate various parallel imaging accelerations by showing the sampling patterns in the phase-encode planes 44, 45, 50, 51, 52, 55.

For instance, FIG. 2B illustrates the sampling pattern without acceleration, thus the acceleration in each phase-encoding direction Ry, Rz is 1.

SENSE and GRAPPA acceleration is illustrated in FIG. 2C. Therein, a SENSE and GRAPPA 2×2 acceleration (i.e., Ry=2, and Rz=2) is achieved by skipping the second and fourth shots in the ky direction, and skipping every second partition in the kz direction.

CAIPIRINHA accelerations may be achieved by introducing a staggered sampling pattern in the ky-kz plane, which helps reduce g-factor related signal-to-noise ratio (SNR) penalties. Example “staggered” sampling patterns are shown in FIGS. 2D to 2G, and are described in further detail below.

The CAIPIRINHA sampling pattern is uniquely determined by the acceleration factors in the ky and the kz directions, R_{y} and R_{z}, and the CAIPIRINHA shift Δ_{y} or Δ_{z}, which is the shift in the sampling pattern between adjacent k-space lines. It is conceivable that the same CAIPIRINHA sampling pattern can be expressed in either Δ_{y} or Δ_{z} notation. Typically, R_{y}, R_{z}, and Δ_{z} can be specified in the protocol. One of the ways to implement CAIPIRINHA with 3D-EPI is to achieve the shift in sampling pattern by employing a shift Δ_{y} between shots of different partitions, instead of employing kz gradient blips to achieve Δ_{z} within the individual shots. This approach is referred to as shot-selective CAIPIRINHA, where kz gradient blips are always zero within each shot. Examples for such shot-selective sampling patterns are shown in FIGS. 2D and 2E.

For better understanding of shot-selective CAIPIRINHA acceleration, the effective acceleration factors, R_{eff,y} and R_{eff,z}, and CAIPIRINHA shift in phase-encoding direction, Δ_{y}, can be calculated in accordance with Eqn. 1 as follows:

$${Δ}_{z} ↦ {Δ}_{y} : \{ \begin{matrix}if {R}_{z} \% {Δ}_{z} = 0 : {R}_{eff , y} = {R}_{y} \cdot {R}_{z} / {Δ}_{z} ; {R}_{eff , z} = {Δ}_{z} ; {Δ}_{y} = {R}_{y} \\ if {R}_{z} \% {Δ}_{z} \neq 0 : {R}_{eff , y} = {R}_{y} \cdot {R}_{z} ; {R}_{eff , z} = 1 ; {Δ}_{y} = {Δ}_{z} \cdot {R}_{y}\end{matrix} \qquad [ 1 ]$$

To create a valid protocol with the shot-selective CAIPIRINHA acceleration, there is an additional requirement that the number of segments S needs to be divisible by R_{eff,y}, namely as represented in Eqn. 2 as follows:

S % R_{eff,y}=0 [2]

where % denote modulo operation.

FIG. 2D illustrates a protocol with R_{y}× R_{z}=2×2 acceleration and Δ_{z}=1. With Δ_{z}=1, the calculated effective values according to [1] are R_{eff,y}× R_{eff,z}=4×1 with Δ_{y}=2. The sampling pattern is identical to the skipped-CAIPI sampling pattern (Ry=2, Rz=2 and shift Δ_{z}=1) with segment=1, as illustrated in FIG. 2G.

FIGS. 2E, 2F, and 2G illustrate examples of skipped-CAIPI sampling patterns (Ry=2, Rz=2 and shift Δ_{z}=1) with no. of segments S=4, 3 and 1, respectively. The sampling patterns of FIGS. 2D to 2E are all identical, but the order of sampling, also referred to herein as reordering, is different. For instance, in skipped-CAIPI sampling patterns, the partitions may be sampled in an interleaved fashion. In other words, a single shot may sample points in different partitions, using kz gradient blips. In FIG. 2F, for example, readout lines in two partitions are alternately acquired in a single shot, as indicated by arrow 53. Altogether, 3 shots/segments are used to sample all k-space lines in one block of two partitions with the prescribed R_{y}×R_{z}=2×2 acceleration. In FIG. 2G, readout lines in two partitions are alternately acquired in a single shot/segment, as indicated by arrow 54.

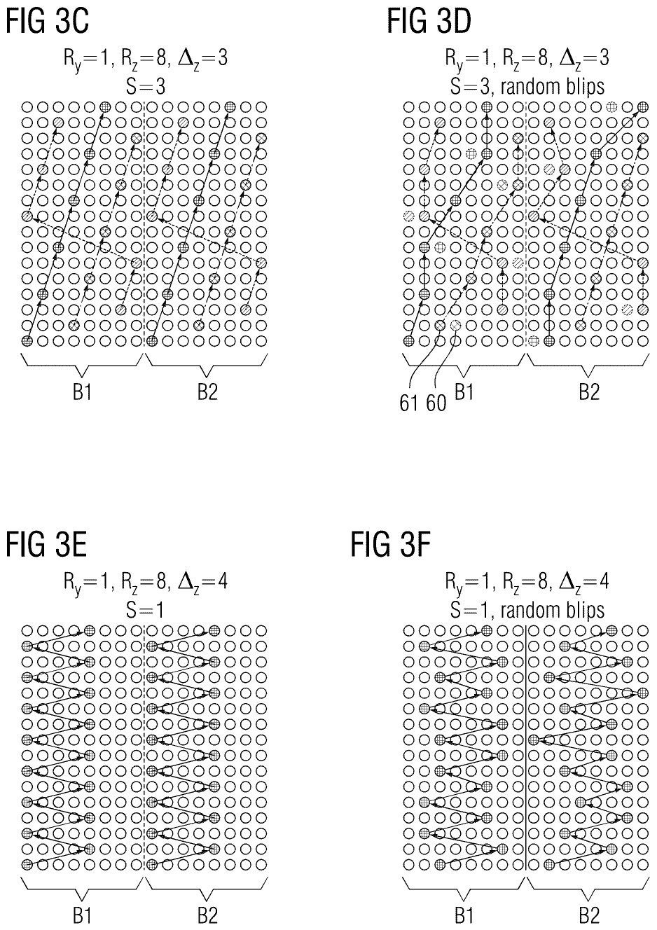

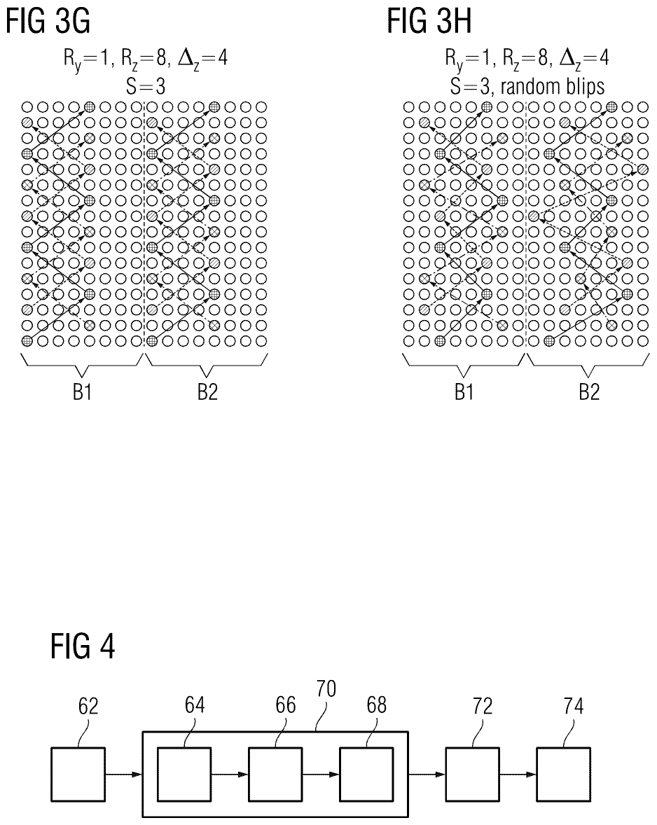

In other words, a skipped-CAIPI reordering scheme is another way to achieve a CAIPIRINHA sampling pattern with 3D-EPI. It allows non-zero kz gradient blips within each EPI readout. Since OA can be readily implemented per shot, it eliminates the needs to convert to Δ_{y} notation, as in Eq. [1]. Nor does it need to satisfy the condition of Eq. [2]. This enables more flexible and more complex 3D k-space reordering. Examples of skipped-CAIPI are provided in FIGS. 3E, 3F, and 3G, where the sampling patterns are identical to the shot-selective CAIPIRINHA in FIG. 2D. Here, every two partitions (R_{z}=2) are completed with 4, 3 and 1 segments in FIGS. 2E, 2F and 2G, respectively. The k-space reordering of skipped-CAIPI with 2 segments is identical to that of the shot-selective case (FIG. 2D).

In some embodiments of the present disclosure, the skipped-CAIPI pattern is adhering to the following step sizes in ky and kz, δ_{y}=SR_{y} and δ_{z}=SΔ_{z}. Additionally, the read-out lines of each shot of the skipped-CAIPI 3D-EPI may be restricted to a block size of R_{z} in the kz direction (e.g., examples FIGS. 2F and 2G use a block size of 2, examples in FIGS. 3A-3H adopt a block size of 8). The actual location of the pth (p∈[1, EPI]) readout lines of the EPI echo train within the q-th block may in some embodiments be written in accordance with Eqn. 3 as:

$$\{ \begin{matrix}{K}_{y} = {K}_{y 0} + p {δ}_{y} \\ {K}_{z} = ( q - 1 ) {R}_{z} + 1 + ( {K}_{z 0} + p {δ}_{z} ) \% {R}_{z}\end{matrix} \qquad [ 3 ]$$

where K_{y0} and K_{z0} are the first read-out line positions of the current EPI read-out train in the ky and the kz directions.

### II. Mathematical Description of Random Trajectories in 3D-EPI

The skipped-CAIPI reordering lends itself well to introducing randomness into the acquisition. According to embodiments of the present disclosure, the acquisition is first separated into blocks of Rz partitions, while each block is independently acquired relative to one another. Secondly, the blip size Δ_{z} in the kz direction can be readily combined with an additional random jitter r_{z}, resulting in an effective blip size Δ_{z}+γ_{z}. In some embodiments, the jitter can be generated on-the-fly during sequence preparation, depending on some probability density function, and optionally other parameters such as the size of the original blip size, Δ_{z}. In embodiments of the present disclosure, the random or pseudo random jitter in the kz direction r_{z} may be described in accordance with Eqn. 4 as follows:

r_{z}≈Δ_{z}· [symbol] (μ,σ²) [4]

where μ∈ [symbol] is the mean or expectation of the probability distribution, σ²∈ [symbol] is the variance, and the sign ≈ indicates that r_{z}∈ [symbol] is the closest integer to the right-hand side. Effectively, with random jitters, the actual location of the p-th read-out lines of the EPI train within the q-th block now become:

$$\{ \begin{matrix}{k}_{y} = {k}_{y 0} + p {δ}_{y} \\ {k}_{z} = ( q - 1 ) {R}_{z} + 1 + ( {k}_{z 0} + p {δ}_{z} + {r}_{z} ) \% {R}_{z}\end{matrix} \qquad [ 5 ]$$

### III. An Overview of an Example Sampling Pattern for Randomly Sampled 3D-EPI

FIGS. 3A-3H illustrate example acquisition patterns for 3D-EPI with and without random jitters, in accordance with embodiments of the present disclosure.

FIG. 3A shows a skipped-CAIPI sampling pattern (R_{y}=1, R_{z}=8, Δ_{z}=3) with S=1, and FIG. 3B shows a similar sampling pattern, but with random or pseudo-random jitter r_{z} added thereto in the kz direction. Specifically, the k-space lines 60 shown in FIG. 3B are moved randomly to positions 61. In the illustrated example, the jitter is either −1, 1, or 0, but evidently in more realistic sampling patterns having more grid points, the jitter may be higher, for example up to 3, 4, 5, 6, etc. (positive or negative). Please note that one integer indicates one grid point or one readout line position in the phase-encode plane.

FIG. 3C shows the skipped-CAIPI sampling pattern as FIG. 3A, but with S=3, and FIG. 3D shows a similar sampling pattern to FIG. 3C, but with random jitter added thereto. Again, the readout lines which are originally positioned at 60 (as in FIG. 3C) are moved through random jitter to new positions 61.

FIG. 3E shows a different skipped-CAIPI sampling pattern (R_{y}=1, R_{z}=8, Δ_{z}=4) with S=1, and FIG. 3F shows a similar sampling pattern, but with random or pseudo-random jitter added thereto. FIG. 3G shows a the same skipped-CAIPI sampling pattern as FIG. 3C, but with S=3, and FIG. 3H shows a similar sampling pattern, but with random or pseudo-random jitter added thereto. Regarding FIGS. 3E and 3G, because the samples are located on the first and fifth partitions, only non-negative jitters (r_{z}≥0) can be accepted. To allow for symmetrically distributed jitters that straddle over zero, the mean of the normal distribution is set to μ=1.5 (assuming first partition corresponds to k_{z}=0), as opposed to μ=0 (e.g., in FIG. 3B and FIG. 3D). This results in skipped-CAIPI pattern with random blips, as shown in FIG. 3F and FIG. 3H.

The sampling patterns as shown in FIGS. 3B, 3D, 3F and 3H may be created in a straightforward fashion, e.g. by introducing small jitters in the kz direction (e.g. the horizontal axis) to the skipped-CAIPI sampling scheme. A significant advantage of doing so is that the ky and kz step sizes are the same or similar to those of the skipped-CAIPI scheme. Specifically, in the present examples as shown in FIGS. 3A-3H, the ky step size is maintained identical to that of the skipped-CAIPI scheme without random or pseudo-random jitter, while the largest kz step size often does not exceed that of the skipped-CAIPI scheme. This translates to an EPI readout with the same or similar echo spacing as the skipped-CAIPI scheme.

Specifically, in an embodiment, the skipped-CAIPI scheme has a regular step size in the ky direction that is equal to δ_{y}=SR_{y} (S=segments, R_{y}=acceleration factor in ky), and a regular step size in the kz direction δ_{z}=SΔ_{z} (S=segments, Δ_{z}=CAIPIRINHA shift in kz). Equation 3 specifies the EPI read-out line positions, K_{y} and K_{z}. Particularly, In the kz direction, the EPI readout line positions K_{z} of a particular shot are restricted to a block B1, B2 of size R_{Z}, namely K_{Z} ∈[(q−1)R_{z}+1, qR_{z}] for the q-th block. This can be observed in examples provided in FIG. 3D and FIGS. 3A, 3C, 3E, and 3G.

Once the skipped-CAIPI pattern is determined, random sampling is introduced by additional jitters in the kz steps. A straightforward way of generating jitter is to allow the amplitude of the jitters to follow a normal distribution, e.g. where the probability density function can be readily adjusted by its mean and standard deviation, as shown in Equation 4. Examples of skipped-CAIPI sampling patterns with and without random jitters are shown in FIGS. 3A-3H. Several variations are provided in FIGS. 3A-3H, e.g. with respect to dividing phase encoding into various numbers of shots (i.e., S=1 or S=3) while maintaining the same overall CAIPIRINHA pattern, which provides the flexibility/capability to adjust echo train length.

For example, and with continued reference to FIGS. 3A-3H, it is noted that acquisition patterns of 3D-EPI are shown with and without random jitters. FIGS. 3A and 3C show a skipped-CAIPI sampling pattern with R_{y}=1, R_{z}=8, Δ_{z}=3, with S=1 and S=3, respectively. FIGS. 3B and 3D show a sampling pattern when random jitters are introduced to those shown in FIGS. 3A and 3C, respectively. FIGS. 3E and 3G show a skipped-CAIPI sampling pattern with R_{y}=1, R_{z}=8, Δ_{z}=4, with S=1 and S=3 respectively. FIGS. 3F and 3H show a sampling pattern when random jitters are introduced to those shown in FIGS. 3E and 3G, respectively.

The embodiments discussed herein provide a random sampling pattern that, in some embodiments, largely follows skipped-CAIPI approach, hence inheriting the benefits thereof, including complete flexibility in configuring the overall acceleration factor, CAIPIRINHA pattern, and EPI train length. Advantages of the skipped-CAIPI include more flexibility in achieving specific TE, TR, read-out bandwidth and EPI factor (also known as, echo train length or ETL) [12]. Specifically, the EPI echo train length may be adjusted by adopting different segments S as shown in the examples of FIGS. 3A-3H, where changing S=1 and S=3, reduces the EPI echo train length from 15 to 5. This is not feasible with the conventional technique described in [7], where the EPI echo train length is determined by the image matrix size in the K_{y} direction.

The randomness in sampling of the embodiments discussed herein may be achieved by jitters in the kz direction (e.g. additional gradient blip sizes in r_{z}) superimposed on top of the skipped-CAIPI gradient blips. The EPI readout line positions in the kz direction, K_{z}, of a particular shot may be restricted to a block B1, B2 of size R_{z}, namely K_{z} ∈[(q−1)R_{z}+1, qR_{z}] for the q-th block. This is true for both skipped-CAIPI (See Eq. 3) and randomly sampled skipped-CAIPI (See Eq. 5). As a result, the actual gradient blip sizes in the kz direction of the random sampling is similar to and may be in some cases no larger than that of skipped-CAIPI. This results in similar echo spacing and overall sequence timing with and without random sampling. For the previous conventional method [6], such implementation has not been described.

The example embodiments described herein thus facilitate the acquisition of data largely following a skipped-CAIPI pattern while allowing small jitters in the kz direction, or in both phase-encoding directions. However, the embodiments as described herein are provided by way of example and not limitation, and may be altered to create alternative implementations. Some examples of such alternative embodiments are provided below:

As described in the exemplary embodiments herein, the randomly sampled skipped-CAIPI may adopt a regular step size in the ky direction, δ_{y}=SR_{y} The overall random sampling patterns are thus provided by random jitters in the kz direction. However, in alternative embodiments, jitter may be provided in any other direction, such as in the ky direction for instance, k_{y}=k_{y0}+nδ_{y}+r_{y}, where r_{y} denotes jitter in the ky direction. However, this may cause changes in echo spacing and overall sequence timing.

Moreover, the EPI readout line positions in k_{z} direction, K_{z}, of a particular shot are described herein as being restricted to a block of size R_{z}, namely K_{z} [(q−1)R_{z}+1, qR_{z}] for the q-th block. However, in alternative embodiments, this restriction may be relaxed, e.g. the kz direction may extend beyond the current block. It is noted that this may result in larger gradient blip sizes in the kz direction. Additionally, this may also result in the situation that the same readout lines are acquired more than once, which has to be treated accordingly by the reconstruction method.

As discussed previously, GRAPPA/SENSE and CAIPIRINHA are “special” cases of skipped-CAIPI, wherein random blips (phase-encode shifts) according to embodiments of the present disclosure can be introduced to these special cases as well. FIG. 2C and FIG. 2D represent example sampling patterns of GRAPPA/SENSE (R_{y}=2, and R_{z}=2) and CAIPIRINHA (R_{y}×R_{z}=2×2 acceleration and Δ_{z}=1), respectively. If one draws a 2×2 square (block) around each readout line, which are represented by the filled circles in FIGS. 2C and 2D, random blips can be introduced to shift the readout line from the original position to either of the other 3 positions in each square, according to some probability density function. This applies to both the GRAPPA/SENSE sampling pattern of FIG. 2C and to the CAIPIRINHA sampling pattern of FIG. 2D. The size of the random blips can be bounded such that the final position of the readout line is within the R_{y}×R_{z} block (i.e., 2×2 in the current examples). Alternatively, larger blip sizes, if allowed, may result in the same readout line being acquired more than once, which needs to be treated accordingly in reconstruction.

### IV. Deep Learning Based Image Reconstruction and Super-Resolution

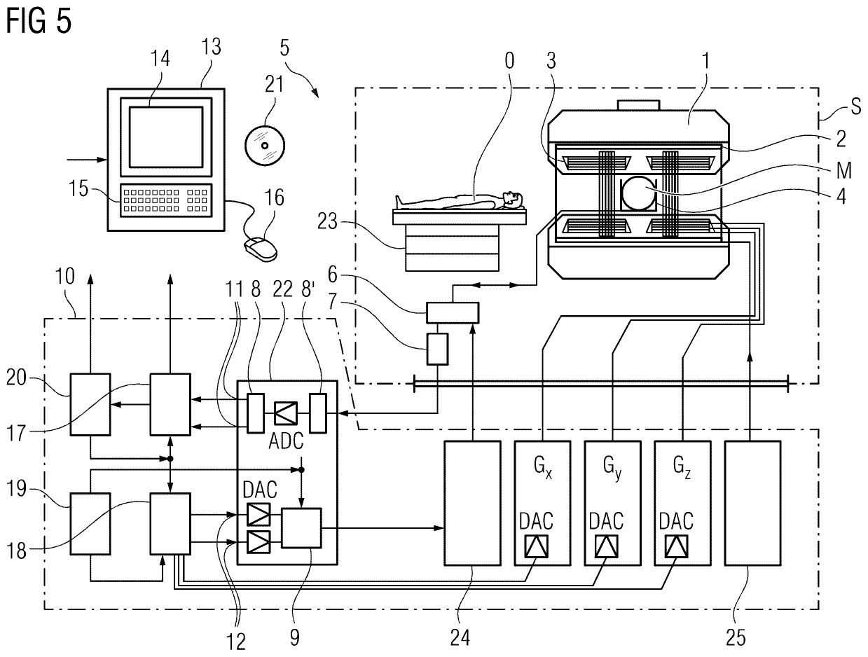

An example of a suitable deep learning reconstruction comprises two independent, sequential processing steps, as illustrated in FIG. 4. The input data to the reconstruction algorithm is the MR data 62 as acquired in the k-space domain. Firstly, images are generated on the acquired resolution using a variational network architecture 70 with any suitable number (six in this example) of iterations that alternate between parallel imaging reconstruction 64 and 3D image regularizations using U-nets 66, optionally followed by a data consistency step 68. Although U-nets are used in this example, it is noted that any suitable type of artificial neural network may be used for the image regularization step, including but not limited to convolutional neural networks (CNNs), residual networks (ResNets), generative adversarial networks (GANs), or other suitable deep learning architectures suitable for image processing.

The network parameters were determined through supervised training based on about 500 fully sampled 3D datasets of head, abdomen, and pelvis from healthy volunteers (no 3D-EPI data included). Secondly, the obtained images were interpolated using a deep learning based super-resolution algorithm 72, with a factor-of-two interpolation in all spatial dimensions. Thereby, the final 3D MR image 74 in the image domain is obtained. It is noted that the specific parameters described herein, such as the number of iterations (e.g., six), the number of training datasets (e.g., 500), the interpolation factor (e.g., factor-of-two), and the types of training data (e.g., head, abdomen, pelvis), are provided by way of example and not limitation. The reconstruction method may be implemented using any suitable number of iterations, training datasets, interpolation factors, and/or types of training data as appropriate for the specific application. In this example, both steps were implemented in PyTorch, trained on a dedicated GPU cluster, and with networks exported for prospective use in the scanner reconstruction pipeline.

### V. Example

Table 1 illustrates a table of parameters for an example imaging protocol used to perform a 3D-EPI combined with deep-learning based reconstruction and super resolution, in accordance with embodiments of the present disclosure. Table 1 identifies the various parameters used for experiments that were performed on a 3T clinical scanner (MAGNETOM Prisma, Siemens Healthcare, Erlangen, Germany) using a 64Rx head coil. A high-resolution T2* 3D-EPI protocol with acceleration factor of 8 was tested with and without random jitters. It is noted that the imaging protocol of the 3D-EPI has a native resolution of 0.65×0.65×2 mm³ and, when combined with deep-learning based reconstruction and super-resolution, the resolution is 0.33×0.33×2 mm³.

TABLE 1

| FOV | | | | Slice | Slice | Flip |
|---|---|---|---|---|---|---|
| read | FOV | Base | No. of | over- | thickness | Angle |
| (mm) | phase | resolution | slices | sampling | (mm) | (°) |
| 224 | 100% | 672 | 80 | 10% | 2 | 10 |

| TE (ms) | TR (ms) | Acceleration | BW (Hz/Px) | EPI | TA (min:sec) |
|---|---|---|---|---|---|
| 20 | 45 | 8 | 514 | 9 | 0:24 |
| | | (1 × 8 × 3)8 | | | |

T2* reconstructed images were produced with and without jitters, in accordance with embodiments of the present disclosure. Comparison of the images during testing and validation shows that the acquisition and reconstruction were performed successfully. The two images have similar contrast and quality overall. However, parallel imaging artifacts could be found in the image without random jitters. There is no difference in the echo spacing, hence TE/TR timing, between the two acquisitions.

In accordance with the embodiments described herein, any suitable type of deep learning-based algorithm may be implemented for the image reconstruction. This approach is analogous to the compressed sensing reconstruction [1], which was originally proposed to exploit random sampling. Compressed sensing typically alternates between parallel imaging reconstruction and L1-norm regularization of the image after some sparsity transform. The latter tends to remove incoherent under-sampling artifacts as a result of the random sampling. Similarly, the deep-learning reconstruction alternates between parallel imaging reconstruction and 3D image regularizations using U-nets [16].

Thus, the embodiments discussed herein facilitate random sampling to be incorporated into 3D-EPI, which provides better parallel imaging performance. This combination may be implemented in a straightforward manner, e.g. by modifying the sequence to include additional jitters of kz gradient blips with random sizes on top of the original fixed-sized gradient blip in the kz direction. This sequence modification does not introduce noticeable changes to ETL, TE, TR, and read-out bandwidth. As a result, the embodiments as discussed herein may be implemented to produce images of similar contrast while reducing parallel imaging artifacts when high acceleration factors are employed.

### VI. An Example Magnetic Resonance Device

FIG. 5 illustrates a representation of an example magnetic resonance device 5 in accordance with one or more embodiments of the present disclosure. The components within the dot-dash outline S are commonly called a magnetic resonance scanner, a magnetic resonance data acquisition scanner, or simply a scanner. The components within the dot-dash outline 10 are commonly called a control unit, a control device, or a control computer.

As shown in FIG. 5, a magnetic resonance device 5 (e.g., a magnetic resonance imaging or tomography device) is shown. The magnetic resonance device 5 may be configured to perform MRI imaging scans in accordance with any suitable sequences, protocols, encoding, and/or techniques, e.g., 2D slice-by-slice or 3D volume acquisitions that may incorporate various encoding techniques, such as those used to perform any of the imaging techniques as discussed herein such as for instance 3D-EPI, SENSE, Simultaneous Multi-Slice (SMS), Controlled Aliasing in Parallel Imaging Results in Higher Acceleration (CAIPRINHA), Generalized Autocalibrating Partially Parallel Acquisitions (GRAPPA), skipped GRAPPA, Controlled Aliasing in Parallel Imaging (CAIPI), skipped CAIPI, etc.

The magnetic resonance apparatus 5 may include additional, fewer, or alternate components that are not depicted in FIG. 5 for purposes of brevity. For instance, the magnetic resonance device 5 may alternatively include, or include in addition to the DVD 21, one or more non-transitory computer-readable data storage media in accordance with various embodiments of the present disclosure. Thus, the aforementioned non-transitory computer-readable media may be loaded, stored, accessed, retrieved, etc., via one or more components accessible to, integrated with, and/or in communication with the magnetic resonance apparatus 5 (e.g., network storage, external memory, etc.). For example, such data-storage mediums and associated program code may be integrated and/or accessed via the terminal 13, the control device 10 or components thereof such as the control computer 20, the image computer 17, the sequence controller 18, the RF system 22, etc.

A main field magnet system 1 generates a temporally-constant strong magnetic field (main magnetic field or B0 field) for the polarization or alignment of the nuclear spin in a region of an examination subject (e.g. a patient) or object O, such as a portion of a human body that is to be examined, and who is lying on a table 23 to be moved into the magnetic resonance apparatus 5. The high degree of homogeneity in the magnetic field generated via the main field magnet system 1 necessary for the magnetic resonance measurement (data acquisition) is defined in a typically sphere-shaped measurement volume M, in which the portion of the human body that is to be examined is placed. To support the homogeneity requirements, temporally-constant effects are eliminated by shim-plates made of ferromagnetic materials that are placed at appropriate positions. Temporally-variable effects are eliminated by shim-coils 2 and an appropriate control unit 25 for the shim-coils 2.

A cylindrically-shaped gradient coil system 3 (or alternatively, gradient field system) is incorporated in the main field magnet system 1, composed of e.g. three or more windings. The gradient coil system 3 is also used to apply a magnetic field gradient, which determines the magnetic resonance frequency (Larmor frequency) at the respective location. Each winding is supplied by a corresponding amplifier Gx, Gy, and Gz, with power for generating a linear gradient field in a respective axis of a Cartesian coordinate system. The first partial winding of the gradient field system 3 generates a gradient Gx in the x-axis, the second partial winding generates a gradient Gy in the y-axis, and the third partial winding generates a gradient Gz in the z-axis. Each corresponding amplifier Gx, Gy, and Gz has a digital-analog converter (DAC), controlled by a sequence controller 18 for the accurately-timed generation of gradient pulses. The gradient field system 3 may utilize one or more of the first, second, or third partial windings of the gradient field system 3 to generate one or more gradients in one or more of the x-axis, the y-axis, and/or the z-axis using a respective Gx, Gy, and/or Gz amplifier. The generated gradients may be used in conjunction with a transmitted RF pulse to receive and process data during acquisition time periods referred to as echoes.

A radio-frequency (RF) antenna 4 is located within the gradient field system 3 and is used to convert the RF pulses provided by a radio-frequency power amplifier 24 into a magnetic alternating field for the excitation of the nuclei by tipping (“flipping”) the spins in the subject or the region thereof to be examined from the alignment produced by the magnetic field generated via the main field magnet system 1. To do so, the radio-frequency antenna 4 is comprised of one or more RF transmitting coils and one or more RF receiving coils in the form of an annular, linear, or matrix type configuration of coils. As the excited nuclear spins relax, RF signals, referred to as magnetic resonance (MR) signals, are emitted in a resonant manner, being received by the RF antenna 4 and then further processed.

Thus, the alternating field based on the precessing nuclear spin, i.e., the nuclear spin echo signal normally produced from a RF pulse sequence composed of one or more RF pulses and one or more gradient pulses, is also converted by the RF receiving coils of the radio-frequency antenna 4 into a voltage (measurement signal), which is transmitted to a radio-frequency system 22 via an RF amplifier 7 of a radio-frequency receiver channel 8, 8′. Acquisition of the MR signals takes place in the spatial frequency space or “k-space,” with k-space being temporally traversed along a “gradient trajectory” that is defined by the switching of the gradient pulses during measurement while the RF pulses are transmitted in a time-coordinated manner. In other words, the MR signals are recorded as “raw data” in k-space along a particular k-space trajectory that is dependent upon the timing of the particular transmitted gradient pulse sequence. The desired image data can then be reconstructed from the recorded raw data in k-space thus acquired by means of a two-dimensional or three-dimensional Fourier transform.

The radio-frequency system 22 further includes a transmitting channel 9, in which the RF pulses for the excitation of the magnetic nuclear resonance are generated. For this purpose, the respective RF pulses are digitally depicted in the sequence controller 18 as a series of complex numbers, based on a given pulse sequence provided by the system computer 20. This number series is sent via an input 12, in each case, as real and imaginary number components to a digital-to-analog converter (DAC) in the radio-frequency system 22 and from there to the transmitting channel 9. The pulse sequences are modulated in the transmitting channel 9 to a RF carrier signal, the base frequency of which corresponds to the resonance frequency of the nuclear spin in the measurement volume. The modulated pulse sequences of the RF transmitter coil are transmitted to the RF antenna 4 via an amplifier 24. Although a single transmission channel and receiving channel are shown and described with reference to FIG. 5, this is for purposes of brevity and provided by way of example and not limitation. The embodiments herein include acquiring MR signals using any suitable type of imaging technique. Thus, the magnetic resonance apparatus 5 may include any suitable number of receiving and/or transmission channels configured for this purpose, and the radio-frequency system 22 may be further modified to facilitate the control, transmission, and reception of data in accordance with any suitable number of channels.

Switching from a transmitting to a receiving operation occurs via a transmission-receiving switch 6. The RF transmitting coil of the radio-frequency antenna 4 radiates the radio-frequency pulse for the excitation of the nuclear spin in the measurement volume M and scans the resulting echo signals via the RF receiving coils. The corresponding magnetic resonance signals obtained thereby are demodulated to an intermediate frequency in a phase sensitive manner in a first demodulator 8′ of the receiving channel of the radio-frequency system 22, and digitized in an analog-digital converter (ADC). This signal is then demodulated to the base frequency. The demodulation to the base frequency and the separation into real and imaginary parts occurs after digitization in the spatial domain in a second demodulator 8, which emits the demodulated data via outputs 11 to an image processor 17.

Therefore, generally predefined pulse sequences determined during measurement, in other words sequences of defined RF pulses as well as gradient pulses in different directions and read-out windows, are used to activate a magnetic resonance tomography system while the receive antennas are switched to receive, and the MR signals are acquired via the process of receiving, processing, and recording these signals as raw data in k-space. To do so, the predefined pulse sequences are generally established beforehand in accordance with any suitable type of measurement protocol together with other control data for the measurement.

In an image processor or image computer 17, an MR image is reconstructed from the measurement data (e.g. the raw data recorded in k-space, which may be referred to herein as acquired k-space data) obtained in this manner, which includes computation of at least one disturbance matrix and the inversion thereof, in the image processor 17. The management of the measurement data, the image data, and the control program occurs via the system computer 20. The sequence controller 18 controls the generation of the desired pulse sequences and the corresponding scanning of k-space with control programs. The sequence controller 18 controls accurately-timed switching (activation) of the gradients, the transmission of the radio-frequency pulse with a defined phase amplitude, and the reception of the magnetic resonance signals. The time base for the radio-frequency system 22 and the sequence controller 18 is provided by a synthesizer 19. The selection of appropriate control programs for the generation of an MR image, which are stored, for example, on a DVD 21 or other suitable storage media. The display of the generated MR images may thus be facilitated via a terminal 13, which includes units for enabling input entries, such as, e.g. a keyboard 15, and/or a mouse 16, and a unit for enabling a display, such as, e.g. a display screen 14.

Thus, the magnetic resonance apparatus 5 as shown in FIG. 5 may include various components to facilitate the measurement, collection, and recording of MR signals as raw data, as well as reconstructing image data from the measured MR signals that are recorded as raw data into an arrangement of k-space. Any of the embodiments described herein may be executed by one or more components of the magnetic resonance apparatus 5, such as for instance the control device 10. For example, the embodiments described herein may be implemented via one or more of the components of the control device 10, such as the system computer 20, the image computer 17, etc., for example to acquire MR image data using random sampling with segmented 3D-EPI, to generate imaging sequences incorporating random or pseudo-random jitter, and/or to perform deep-learning based iterative reconstruction and super-resolution.

The techniques as discussed herein may be implemented as an algorithm, for example, which is enabled via execution of computer-readable instructions by one or more of the components of the control device 10. The computer-readable instructions may be stored in any suitable type of machine-readable medium (e.g. a non-transitory computer-readable medium) integrated with the control device 10 or other suitable location accessible via the control device 10. The algorithms may include any of those discussed herein, for example to acquire MR image data using random sampling with segmented 3D-EPI, to generate imaging sequences incorporating random or pseudo-random jitter, and/or to perform deep-learning based iterative reconstruction and super-resolution, which may include storing, training, and/or executing such algorithms using any suitable techniques.

### REFERENCES

The following references are cited throughout this disclosure as applicable to provide additional clarity, particularly with regards to terminology. These citations are made by way of example and ease of explanation and not by way of limitation. Citations to the following references are made throughout the application using a matching bracketed number, e.g., [1].
[1]. Lustig, M., Donoho, D. & Pauly, J. M. Sparse MRI: The application of compressed sensing for rapid MR imaging. Magnetic Resonance in Medicine 58, 1182-1195 (2007).
[2]. Gong, E. et al. PROMISE: Parallel-imaging and compressed-sensing reconstruction of multicontrast imaging using SharablE information. Magnetic Resonance in Medicine 73, 523-535 (2015).
[3]. Han, F. et al. Four-dimensional, multiphase, steady-state imaging with contrast enhancement (MUSIC) in the heart: A feasibility study in children. Magnetic Resonance in Medicine 74, 1042-1049 (2015).
[4]. Adluru, G. et al. Three-dimensional late gadolinium enhancement imaging of the left atrium with a hybrid radial acquisition and compressed sensing. Journal of Magnetic Resonance Imaging 34, 1465-1471 (2011).
[5]. Feng, L. et al. XD-GRASP: Golden-Angle Radial MRI with Reconstruction of Extra Motion-State Dimensions Using Compressed Sensing. Magn Reson Med 75, 775-788 (2016).
[6]. Liebig, P., Heidemann, R., Hensel, B. & Porter, D. Highly Accelerated 3D EPI using Compressed Sensing. in Proc. Annu. Meeting ISMRM vol. 27 4579 (2019).
[7]. Liebig, P. A., Heidemann, R. M., Hensel, B. & Porter, D. A. A new approach to accelerate readout segmented EPI with compressed sensing. Magnetic Resonance in Medicine 84, 321-326 (2020).
[8]. Zwanenburg, J. J. M., Versluis, M. J., Luijten, P. R. & Petridou, N. Fast high resolution whole brain T2* weighted imaging using echo planar imaging at 7T. NeuroImage 56, 1902-1907 (2011).
[9]. Jin Jin et al. Segmented 3D EPI with CAIPIRINHA for Fast, High-Resolution T2*-weighted Imaging. in Proc. Annu. Meeting ISMRM (2021).
[10]. Poser, B. A., Koopmans, P. J., Witzel, T., Wald, L. L. & Barth, M. Three dimensional echo-planar imaging at 7 Tesla. NeuroImage 51, 261-266 (2010).
[11]. Poser, B. et al. CAIPIRINHA-Accelerated 3D EPI for High Temporal and/or Spatial Resolution EPI Acquisitions. In: Proc. Eur. Soc. Magn. Reson. Med. B (2013).
[12]. Stirnberg, R. & Stocker, T. Segmented K-space blipped-controlled aliasing in parallel imaging for high spatiotemporal resolution EPI. Magnetic Resonance in Medicine 85, 1540-1551 (2021).
[13]. Griswold, M. A. et al. Generalized autocalibrating partially parallel acquisitions (GRAPPA). Magnetic Resonance in Medicine 47, 1202-1210 (2002).
[14]. Breuer, F. A. et al. Controlled aliasing in volumetric parallel imaging (2D CAIPIRINHA). Magnetic Resonance in Medicine 55, 549-556 (2006).
[15]. Tourell, M. et al. Three-dimensional EPI with shot-selective CAIPIRIHANA for rapid high-resolution quantitative susceptibility mapping at 3 T. Magnetic Resonance in Medicine 88-98 (2024) doi:10.1002/mrm.30101.
[16]. Hammernik, K. et al. Learning a variational network for reconstruction of accelerated MRI data. Magnetic Resonance in Medicine 79, 3055-3071 (2018).
[17]. Almansour, H. et al. Deep Learning-Based Superresolution Reconstruction for Upper Abdominal Magnetic Resonance Imaging: An Analysis of Image Quality, Diagnostic Confidence, and Lesion Conspicuity. Investigative Radiology 56, (2021).

### CONCLUSION

The embodiments described above are to be recognized as examples. It is to be understood that individual embodiments may be extended by or combined with features of other embodiments if not stated otherwise. For example, the embodiments are discussed herein in the context of 3D-EPI imaging. Although this is a particularly advantageous use of the embodiments as discussed herein, this is by way of example and not limitation, and the embodiments discussed herein may be implemented in accordance with any suitable MR imaging encoding, sequences, protocols, etc.

The various components described herein may be referred to as “devices” or “units.” As noted above, such components may be implemented via any suitable combination of hardware and/or software components as applicable and/or known to achieve the intended respective functionality. This may include mechanical and/or electrical components, processors, processing circuitry, or other suitable hardware components configured to execute instructions or computer programs that are stored on a suitable computer readable medium. Regardless of the particular implementation, such devices and units, as applicable and relevant, may alternatively be referred to herein as “circuitry,” “processors,” or “processing circuitry.”

In this text, independent of the grammatical term usage, individuals with male, female or other gender identities are included within the term.

What is claimed is:

1. A method for acquiring magnetic resonance (MR) image data of an object by performing a three-dimensional echo-planar imaging sequence, the method comprising:
sampling a three-dimensional k-space via at least one shot comprising:
applying a radio-frequency (RF) excitation to the object to generate an MR signal;
spatially encoding, via gradients in the phase-encoding directions, the MR signal along two phase-encoding directions k_{y} and k_{z} that together span a phase-encode plane; and
acquiring, while applying read-out gradients along a frequency encoding direction kₓ, a number of k-space lines at different positions in the phase-encode plane,
wherein the k-space is sampled in a sampling pattern that undersamples the k-space in the phase-encode plane, and
wherein the sampling pattern includes a random or pseudo-random jitter such that one or more k-space lines are randomly or pseudo-randomly shifted in the k_{y} and/or the k_{z} direction.

2. The method according to claim 1, further comprising:
generating the sampling pattern by:
receiving a parallel imaging sampling pattern; and
introducing a random or pseudo-random jitter such that one or more k-space lines are randomly or pseudo-randomly shifted with respect to the parallel imaging sampling pattern in the k_{y} and/or the k_{z} direction.

3. The method according to claim 2, wherein the parallel imaging sampling pattern comprises, before the random or pseudo-random jitter is introduced, a Sensitivity Encoding/Generalized Autocalibrating Partially Parallel Acquisitions (SENSE/GRAPPA) sampling pattern.

4. The method according to claim 2, wherein the parallel imaging sampling pattern comprises, before the random or pseudo-random jitter is introduced, a Controlled Aliasing in Parallel Imaging Results in Higher Acceleration (CAIPIRINHA) sampling pattern.

5. The method according to claim 2, wherein the parallel imaging sampling pattern comprises, before the random or pseudo-random jitter is introduced, a skipped Controlled Aliasing in Parallel Imaging (skipped-CAIPI) sampling pattern.

6. The method according to claim 1, wherein the k-space is divided in the k_{z} phase-encoding direction into a series of blocks, and
wherein each block of the series of blocks is sampled in one or multiple shots.

7. The method according to claim 1, wherein the k-space is divided in the k_{z} phase-encoding direction into a series of partitions, and
wherein the k-space direction in which the one or more k-space lines are shifted to include the random or pseudo-random jitter comprises the k_{z} direction.

8. The method according to claim 1, and wherein the k-space lines are shifted in one single phase-encoding direction to include the random or pseudo-random jitter.

9. The method according to claim 1, further comprising:
generating the random or pseudo-random jitter during preparation of the imaging sequence.

10. The method according to claim 1, further comprising:
generating the random or pseudo-random jitter according to a probability density function.

11. The method according to claim 1, wherein the sampling pattern comprises a regular sampling pattern arranged on a Cartesian grid in the phase-encode plane, and
wherein the random or pseudo-random jitter has an absolute value between 0 and 5 grid points.

12. The method according to claim 2, wherein the parallel imaging sampling pattern has an acceleration factor in at least one phase-encoding direction, and is arranged on a Cartesian grid in the phase-encode plane, and
wherein the random or pseudo-random jitter has an absolute value between 0 and the acceleration factor.

13. The method according to claim 2, wherein the parallel imaging sampling pattern has an acceleration factor in at least one phase-encoding direction, and is arranged on a Cartesian grid in the phase-encode plane, and
wherein the random or pseudo-random jitter is generated by a probability density function having a mean absolute value between 0.1 and 1 of the acceleration R in the respective phase-encoding direction.

14. The method according to claim 1, wherein the k-space is divided in the k_{z} phase-encoding direction into a series of partitions, and
wherein the random or pseudo-random jitter has a negative or non-negative value based upon a sequential number of the one or more of the series of partitions to which the jitter is introduced.

15. The method according to claim 1, further comprising:
reconstructing an MR image from MR data acquired of the object by:
receiving MR data of the object in k-space; and
applying a deep-learning based reconstruction algorithm to the MR data in k-space to thereby generate a reconstructed MR image.

16. The method of claim 15, further comprising:
applying a deep-learning based super-resolution algorithm to the reconstructed MR image to thereby generate an MR image having increased resolution.

17. The method of claim 16, wherein the deep-learning based reconstruction algorithm is executed via a plurality of iterations of a parallel-imaging type reconstruction step, an image regularization step, and a data consistency step.

18. The method of claim 17, wherein the image regularization step is executed via an artificial neural network.

19. A method for generating an imaging sequence for acquiring magnetic resonance (MR) image data of an object based on three-dimensional echo-planar imaging, the method comprising:
using a sampling scheme in which a three-dimensional k-space is sampled via at least one shot comprising:
applying a radio-frequency (RF) excitation to the object to generate an MR signal;
spatially encoding, via gradients in the phase-encoding directions, the MR signal along two phase-encoding directions k_{y} and k_{z} that together span a phase-encode plane;
acquiring, while applying read-out gradients along a frequency encoding direction kₓ, a number of k-space lines at different positions in the phase-encode plane,
wherein the k-space is sampled in a sampling pattern that undersamples the k-space in the phase-encode plane; and
generating the sampling pattern by:
receiving a parallel imaging sampling pattern; and
introducing a random or pseudo-random jitter such that one or more k-space lines are randomly or pseudo-randomly shifted with respect to the parallel imaging sampling pattern in the k_{y} and/or the k_{z} direction.

20. A magnetic resonance (MR) imaging device configured to perform three-dimensional echo-planar imaging (3D-EPI) of an object, the MR imaging device comprising:
a main magnet; and
processing circuitry configured to acquire MR image data of the object by performing a 3D-EPI sequence that includes sampling a three-dimensional k-space via at least one shot comprising:
applying a radio-frequency (RF) excitation to the object to generate an MR signal;
spatially encoding, via gradients in the phase-encoding directions, the MR signal along two phase-encoding directions k_{y} and k_{z} that together span a phase-encode plane; and
acquiring, while applying read-out gradients along a frequency encoding direction kₓ, a number of k-space lines at different positions in the phase-encode plane,
wherein the k-space is sampled in a sampling pattern that undersamples the k-space in the phase-encode plane, and
wherein the sampling pattern includes a random or pseudo-random jitter such that one or more k-space lines are randomly or pseudo-randomly shifted with respect to a parallel imaging sampling pattern in the k_{y} and/or the k_{z} direction.
